(19) United States
(12) Patent Application Publication
(10) Pub. No.: US 2007/0059938 A1
(43) Pub. Date: Mar. 15, 2007

(54) Method and system for etching silicon oxide and silicon nitride with high selectivity relative to silicon

(76) Inventors: Hanako Kida, Watertown, MA (US); Masaaki Hagihara, Peabody, MA (US); Akiteru Ko, Peabody, MA (US)

Correspondence Address: DLA PIPER US LLP, P. O. BOX 9271, RESTON, VA, 20195, US

(21) Appl. No.: 11/226,452

(22) Filed: Sep. 15, 2005

(51) Int. Cl. H01L 21/302

(52) U.S. Cl. 438/710

(57) ABSTRACT

A method and system for etching features in a substrate, whereby silicon oxide or silicon nitride or both are etched with high selectivity relative to silicon. In one embodiment, the process chemistry utilized to achieve high selectivity includes trifluoromethane (CHF₃), difluoromethane (CH₂F₂), an oxygen containing gas, such as O₂, and an optional inert gas, such as argon.

### FIELD OF THE INVENTION

The present invention relates to a method and system for etching silicon oxide or silicon nitride with high selectivity relative to silicon.

### BACKGROUND OF THE INVENTION

Typically, during fabrication of integrated circuits (ICs), semiconductor production equipment utilize a (dry) plasma etch process to remove or etch material along fine lines or within vias or contacts patterned on a semiconductor substrate. The success of the plasma etch process requires that the etch chemistry includes chemical reactants suitable for selectively etching one material while substantially not etching another material. For example, on a semiconductor substrate, a pattern formed in a protective layer can be transferred to an underlying layer of a selected material utilizing a plasma etching process. The protective layer can comprise a light-sensitive layer, such as a photoresist layer, having a pattern formed using a lithographic process. Once the pattern is formed, the semiconductor substrate is disposed within a plasma processing chamber, and an etching chemistry is formed that selectively etches the underlying layer while minimally etching the protective layer. This etch chemistry is produced by introducing an ionizable, dissociative gas mixture having parent molecules comprising molecular constituents capable of reacting with the underlying layer while minimally reacting with the protective layer. The production of the etch chemistry comprises introduction of the gas mixture and formation of plasma when a portion of the gas species present are ionized following a collision with an energetic electron. Moreover, the heated electrons serve to dissociate some species of the gas mixture and create a reactive mixture of chemical constituents (of the parent molecules). The etch process is adjusted to achieve optimal conditions, including an appropriate concentration of desirable reactant and ion populations to etch various features (e.g., trenches, vias, contacts, etc.) in the exposed regions of substrate. Such substrate materials where etching is required include silicon oxide, polysilicon or silicon nitride, for example.

### SUMMARY OF THE INVENTION

The present invention relates to a method for etching a substrate using a dry plasma process. In particular, the present invention relates to a method for selectively etching a silicon oxide layer or a silicon nitride layer or both relative to a silicon feature on the substrate.

According to an embodiment, a method of etching a substrate is described. The method comprises disposing the substrate in a plasma processing system, wherein the substrate comprises at least one silicon feature, and either a silicon oxide layer or a silicon nitride layer coupled to the silicon feature. Additionally, the method comprises introducing a process gas comprising trifluoromethane (CHF₃), difluoromethane (CH₂F₂), an oxygen containing gas, and an optional inert gas. Furthermore, the method comprises forming plasma from the process gas in the plasma processing system, and exposing the substrate to the plasma in order to selectively etch the silicon oxide layer or the silicon nitride layer relative to the silicon feature. Furthermore, according to another embodiment, a computer readable medium is employed which includes a program for performing the method.

According to yet another embodiment, a plasma processing system configured to etch a substrate is described. The plasma processing system comprises a plasma processing chamber for facilitating the formation of a plasma from a process gas in order to etch a silicon oxide layer or a silicon nitride layer with high selectivity relative to a silicon feature, and a controller coupled to the plasma processing chamber and configured to execute a process recipe utilizing the process gas, the process gas comprises trifluoromethane (CHF₃), difluoromethane (CH₂F₂), an oxygen containing gas, and an optional inert gas.

### BRIEF DESCRIPTION OF THE DRAWINGS

In the accompanying drawings:

FIGS. 1A and 1B show a schematic representation of a typical procedure for pattern etching a thin film;

FIG. 2 shows a simplified schematic diagram of a plasma processing system according to an embodiment of the present invention;

FIG. 3 shows a schematic diagram of a plasma processing system according to another embodiment of the present invention;

FIG. 4 shows a schematic diagram of a plasma processing system according to another embodiment of the present invention;

FIG. 5 shows a schematic diagram of a plasma processing system according to another embodiment of the present invention;

FIG. 6 shows a schematic diagram of a plasma processing system according to another embodiment of the present invention; and

FIG. 7 presents a method of etching a substrate in a plasma processing system according to an embodiment of the present invention.

### DETAILED DESCRIPTION OF SEVERAL EMBODIMENTS

In the following description, to facilitate a thorough understanding of the invention and for purposes of explanation and not limitation, specific details are set forth, such as a particular geometry of the plasma processing system configured to perform an etching process and various descriptions of the system components. However, it should be understood that the invention may be practiced with other embodiments that depart from these specific details.

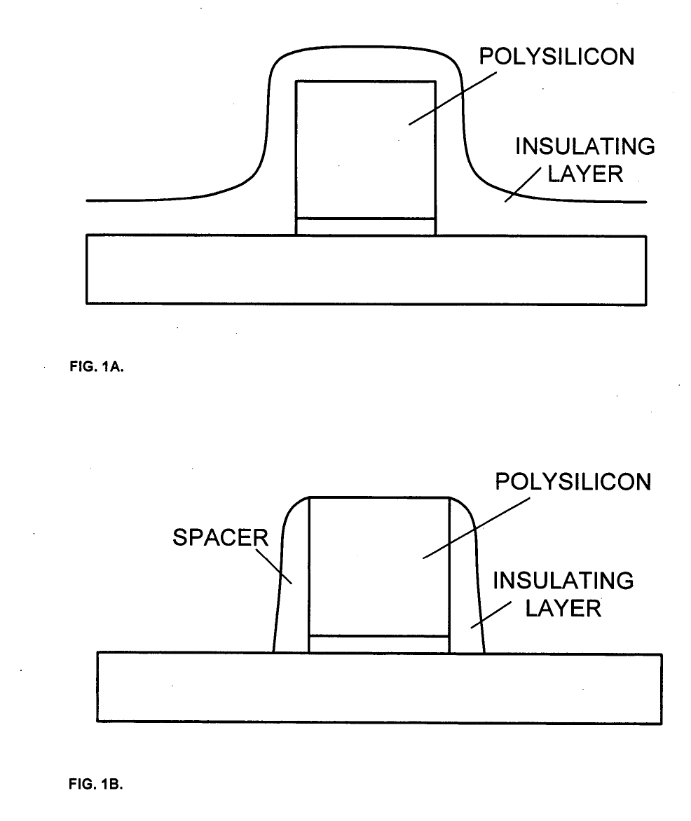

In material processing methodologies, dry plasma etching utilizes a plasma chemistry having chemical reactants suitable for selectively etching one material while substantially not etching another material. In one example, a layer of insulating material is deposited over a polysilicon gate stack, see FIG. 1A. For example, the insulating layer may comprise silicon oxide (e.g., SiO₂), or silicon nitride (e.g., Si₂N₃), or both. Then, the insulating layer is subjected to an etching process, whereby the insulating layer is removed in all locations except along the sidewalls of the gate stack; see FIG. 1B. The remaining insulating material acts as an insulating spacer in the fabrication of the semiconductor device. In order to effectively form the spacer, an etch chemistry is chosen to etch the insulating material while minimally etching the underlying polysilicon.

In one embodiment, the etch chemistry comprises trifluoromethane (CHF₃), difluoromethane (CH₂F₂), and an oxygen containing gas. The oxygen containing gas can comprise oxygen (O₂), NO, N₂O, NO₂, CO, or CO₂, or any combination of two or more thereof. Additionally, the etch chemistry can further comprise an inert gas, such as a noble gas (e.g., argon, krypton, xenon, etc.). For example, one process recipe for etching silicon oxide or silicon nitride with high selectivity to silicon comprises trifluoromethane (CHF₃), difluoromethane (CH₂F₂), oxygen (O₂), and argon (Ar).

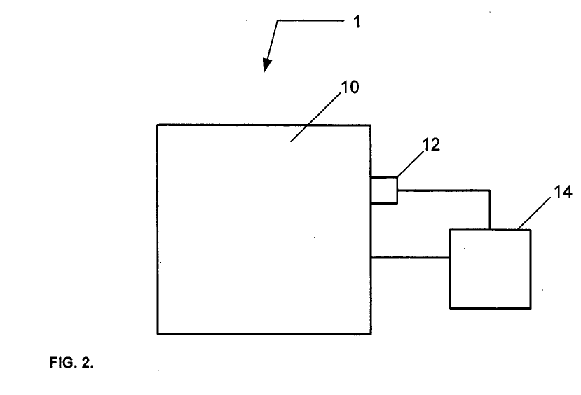

According to one embodiment, a plasma processing system 1 is depicted in FIG. 2 comprising a plasma processing chamber 10, a diagnostic system 12 coupled to the plasma processing chamber 10, and a controller 14 coupled to the diagnostic system 12 and the plasma processing chamber 10. The controller 14 is configured to execute a process recipe comprising trifluoromethane (CHF₃), difluoromethane (CH₂F₂), and an oxygen containing gas to selectively etch silicon oxide or silicon nitride relative to silicon. In one embodiment, the process recipe comprises trifluoromethane (CHF₃), difluoromethane (CH₂F₂), oxygen (O₂), and argon (Ar). Additionally, controller 14 is configured to receive at least one endpoint signal from the diagnostic system 12 and to post-process the at least one endpoint signal in order to accurately determine an endpoint for the process. In the illustrated embodiment, plasma processing system 1, depicted in FIG. 2, utilizes a plasma for material processing. Plasma processing system 1 can comprise an etch chamber.

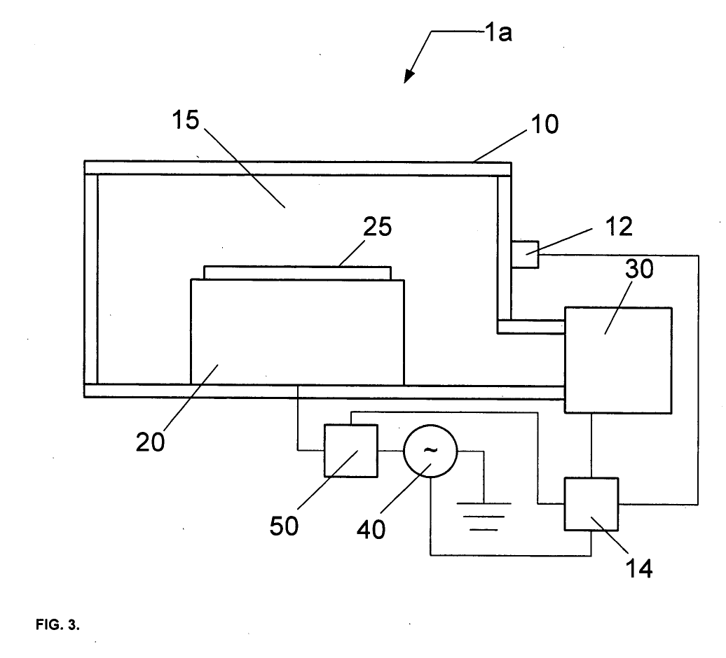

According to the embodiment depicted in FIG. 3, plasma processing system 1a can comprise plasma processing chamber 10, substrate holder 20, upon which a substrate 25 to be processed is affixed, and vacuum pumping system 30. Substrate 25 can be a semiconductor substrate, a wafer or a liquid crystal display. Plasma processing chamber 10 can be configured to facilitate the generation of plasma in processing region 15 adjacent a surface of substrate 25. An ionizable gas or mixture of gases is introduced via a gas injection system (not shown) and the process pressure is adjusted. For example, a control mechanism (not shown) can be used to throttle the vacuum pumping system 30. Plasma can be utilized to create materials specific to a pre-determined materials process, and/or to aid the removal of material from the exposed surfaces of substrate 25. The plasma processing system 1a can be configured to process substrates of any size, such as 200 mm substrates, 300 mm substrates, or larger.

Substrate 25 can be affixed to the substrate holder 20 via an electrostatic clamping system. Furthermore, substrate holder 20 can further include a cooling system including a re-circulating coolant flow that receives heat from substrate holder 20 and transfers heat to a heat exchanger system (not shown), or when heating, transfers heat from the heat exchanger system. Moreover, gas can be delivered to the back-side of substrate 25 via a backside gas system to improve the gas-gap thermal conductance between substrate 25 and substrate holder 20. Such a system can be utilized when temperature control of the substrate is required at elevated or reduced temperatures. The backside gas system can comprise a two-zone gas distribution system, wherein the helium gas gap pressure can be independently varied between the center and the edge of substrate 25. In other embodiments, heating/cooling elements, such as resistive heating elements, or thermo-electric heaters/coolers can be included in the substrate holder 20, as well as the chamber wall of the plasma processing chamber 10 and any other component within the plasma processing system 1a.

In the embodiment shown in FIG. 3, substrate holder 20 can comprise an electrode through which RF power is coupled to the processing plasma in process space 15. For example, substrate holder 20 can be electrically biased at a RF voltage via the transmission of RF power from a RF generator 40 through an impedance match network 50 to substrate holder 20. The RF bias can serve to heat electrons to form and maintain plasma. In this configuration, the system can operate as a reactive ion etch (RIE) reactor, wherein the chamber and an upper gas injection electrode serve as ground surfaces. A typical frequency for the RF bias can range from about 0.1 MHz to about 100 MHz. RF systems for plasma processing are well known to those skilled in the art.

Alternately, RF power is applied to the substrate holder electrode at multiple frequencies. Furthermore, impedance match network 50 serves to improve the transfer of RF power to plasma in plasma processing chamber 10 by reducing the reflected power. Match network topologies (e.g. L-type, π-type, T-type, etc.) and automatic control methods are well known to those skilled in the art.

Vacuum pump system 30 can include a turbo-molecular vacuum pump (TMP) capable of a pumping speed up to about 5000 liters per second (and greater) and a gate valve for throttling the chamber pressure. In conventional plasma processing devices utilized for dry plasma etch, a 1000 to 3000 liter per second TMP is generally employed. TMPs are useful for low pressure processing, typically less than about 50 mTorr. For high pressure processing (i.e., greater than about 100 mTorr), a mechanical booster pump and dry roughing pump can be used. Furthermore, a device for monitoring chamber pressure (not shown) can be coupled to the plasma processing chamber 10. The pressure measuring device can be, for example, a Type 628B Baratron absolute capacitance manometer commercially available from MKS Instruments, Inc. (Andover, Mass.).

Controller 14 comprises a microprocessor, memory, and a digital I/O port capable of generating control voltages sufficient to communicate and activate inputs to plasma processing system 1a as well as monitor outputs from plasma processing system 1a. Moreover, controller 14 can be coupled to and can exchange information with RF generator 40, impedance match network 50, the gas injection system (not shown), vacuum pump system 30, as well as the backside gas delivery system (not shown), the substrate/substrate holder temperature measurement system (not shown), and/or the electrostatic clamping system (not shown). For example, a program stored in the memory can be utilized to activate the inputs to the aforementioned components of plasma processing system 1a according to a process recipe in order to perform the method of etching described herein. One example of controller 14 is a DELL PRECISION WORKSTATION 610™, available from Dell Corporation, Austin, Tex.

However, the controller 14 may be implemented as a general purpose computer system that performs a portion or all of the microprocessor based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The controller 14 includes at least one computer readable medium or memory, such as the controller memory, for holding instructions programmed according to the teachings of the invention and for containing data structures, tables, records, or other data that may be necessary to implement embodiments of the present invention. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, controller 14 includes software for driving a device or devices, and/or for enabling the controller to interact with a human user. Such software may include, but is not limited to, device drivers, operating systems, development tools, and applications software. Such computer readable media further includes the computer program product for performing all or a portion (if processing is distributed) of the processing performed in implementing the embodiment.

The computer code devices may be any interpretable or executable code mechanism, including but not limited to scripts, interpretable programs, dynamic link libraries (DLLs), Java classes, and complete executable programs. Moreover, parts of the processing may be distributed for better performance, reliability, and/or cost.

The term “computer readable medium” as used herein refers to any medium that participates in providing instructions to the processor of the controller 14 for execution. A computer readable medium may take many forms, including but not limited to, non-volatile media, volatile media, and transmission media. Non-volatile media includes, for example, optical, magnetic disks, and magneto-optical disks, such as the hard disk or the removable media drive. Volatile media includes dynamic memory, such as the main memory. Moreover, various forms of computer readable media may be involved in carrying out one or more sequences of one or more instructions to processor of controller for execution. For example, the instructions may initially be carried on a magnetic disk of a remote computer. The remote computer can load the instructions for implementing all or a portion of the present invention remotely into a dynamic memory and send the instructions over a network to the controller 14.

Controller 14 may be locally located relative to the plasma processing system 1a, or it may be remotely located relative to the plasma processing system 1a via an internet or intranet. Thus, controller 14 can exchange data with the plasma processing system 1a using at least one of a direct connection, an intranet, or the internet. Controller 14 may be coupled to an intranet at a customer site (i.e., a device maker, etc.), or coupled to an intranet at a vendor site (i.e., an equipment manufacturer). Furthermore, another computer (i.e., controller, server, etc.) can access controller 14 to exchange data via at least one of a direct connection, an intranet, or the internet.

The diagnostic system 12 can include an optical diagnostic subsystem (not shown). The optical diagnostic subsystem can comprise a detector such as a (silicon) photodiode or a photomultiplier tube (PMT) for measuring the light intensity emitted from the plasma. The diagnostic system 12 can further include an optical filter such as a narrow-band interference filter. In an alternate embodiment, the diagnostic system 12 can include at least one of a line CCD (charge coupled device), a CID (charge injection device) array, and a light dispersing device such as a grating or a prism. Additionally, diagnostic system 12 can include a monochromator (e.g., grating/detector system) for measuring light at a given wavelength, or a spectrometer (e.g., with a rotating grating) for measuring the light spectrum such as, for example, the device described in U.S. Pat. No. 5,888,337.

The diagnostic system 12 can include a high resolution Optical Emission Spectroscopy (OES) sensor such as from Peak Sensor Systems, or Verity Instruments, Inc. Such an OES sensor has a broad spectrum that spans the ultraviolet (UV), visible (VIS), and near infrared (NIR) light spectrums. The resolution can be approximately 1.4 Angstroms, that is, the sensor is capable of collecting about 5550 wavelengths from 240 to 1000 nm. For example, the OES sensor can be equipped with high sensitivity miniature fiber optic UV-VIS-NIR spectrometers which are, in turn, integrated with 2048 pixel linear CCD arrays.

The spectrometers receive light transmitted through single and bundled optical fibers, where the light output from the optical fibers is dispersed across the line CCD array using a fixed grating. Similar to the configuration described above, light transmitted through an optical vacuum window is focused onto the input end of the optical fibers via a convex spherical lens. Three spectrometers, each specifically tuned for a given spectral range (UV, VIS and NIR), form a sensor for a process chamber. Each spectrometer includes an independent A/D converter. And lastly, depending upon the sensor utilization, a full emission spectrum can be recorded from about every 0.1 to about every 1.0 seconds.

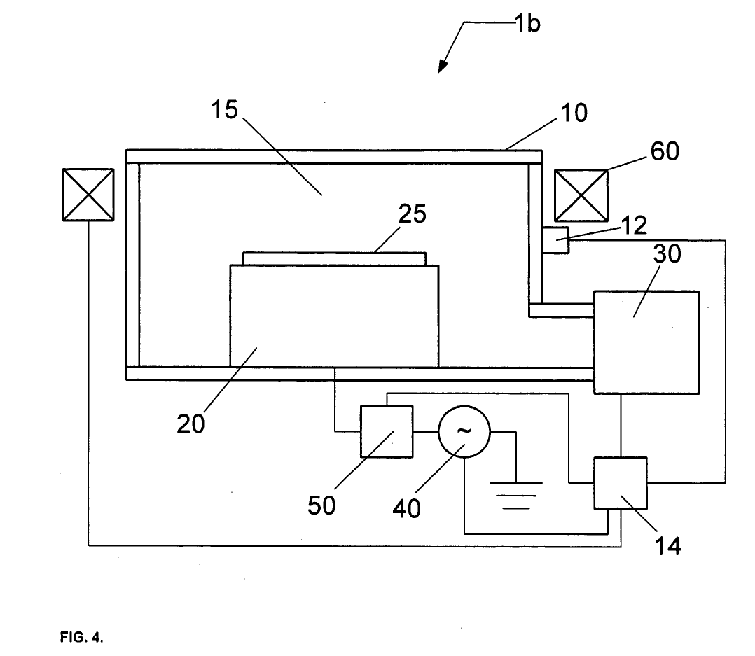

In the embodiment shown in FIG. 4, the plasma processing system 1b can be similar to the embodiment of FIG. 2 or 3 and further comprise either a stationary, or mechanically or electrically rotating magnetic field system 60, in order to potentially increase plasma density and/or improve plasma processing uniformity, in addition to those components described with reference to FIG. 2 and FIG. 3. Moreover, controller 14 can be coupled to magnetic field system 60 in order to regulate the speed of rotation and field strength. The design and implementation of a rotating magnetic field is well known to those skilled in the art.

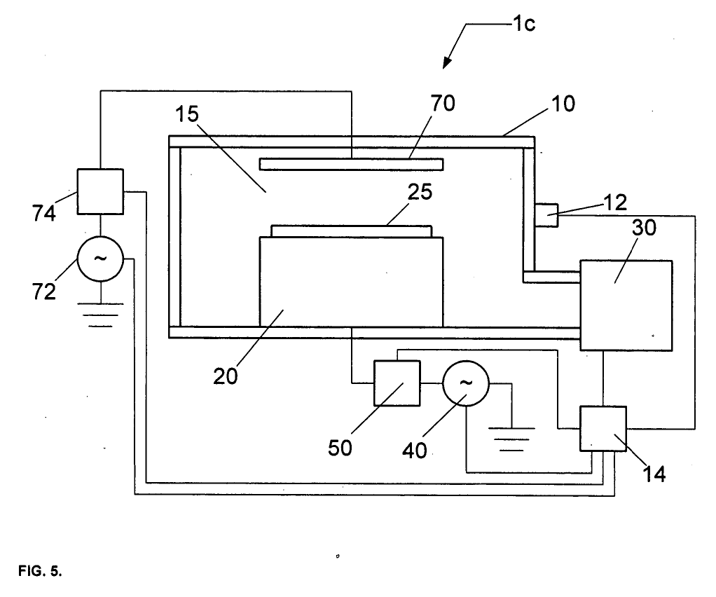

In the embodiment shown in FIG. 5, the plasma processing system 1c can be similar to the embodiment of FIG. 2 or FIG. 3, and can further comprise an upper electrode 70 to which RF power can be coupled from RF generator 72 through impedance match network 74. A typical frequency for the application of RF power to the upper electrode can range from about 0.1 MHz to about 200 MHz. Additionally, a typical frequency for the application of power to the lower electrode can range from about 0.1 MHz to about 100 MHz. Moreover, controller 14 is coupled to RF generator 72 and impedance match network 74 in order to control the application of RF power to upper electrode 70. The design and implementation of an upper electrode is well known to those skilled in the art.

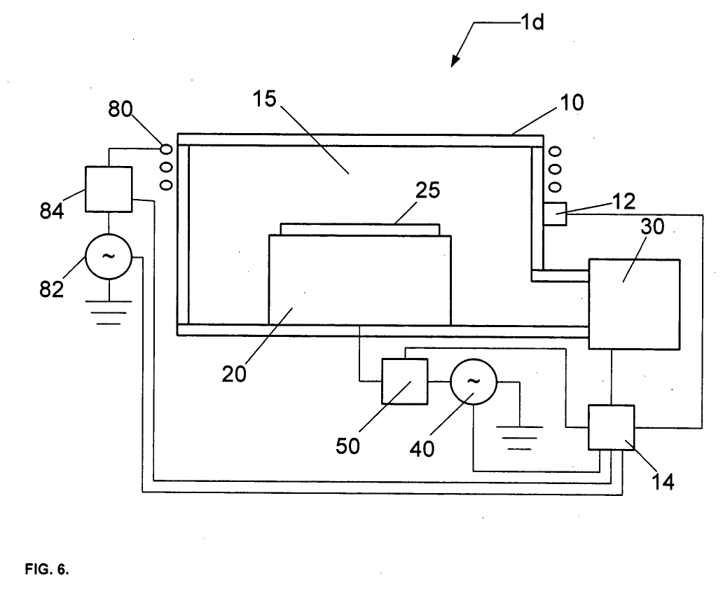

In the embodiment shown in FIG. 6, the plasma processing system 1d can be similar to the embodiments of FIGS. 2 and 3, and can further comprise an inductive coil 80 to which RF power is coupled via RF generator 82 through impedance match network 84. RF power is inductively coupled from inductive coil 80 through dielectric window (not shown) to plasma processing region 15. A typical frequency for the application of RF power to the inductive coil 80 can range from about 10 MHz to about 100 MHz. Similarly, a typical frequency for the application of power to the chuck electrode can range from about 0.1 MHz to about 100 MHz. In addition, a slotted Faraday shield (not shown) can be employed to reduce capacitive coupling between the inductive coil 80 and plasma. Moreover, controller 14 is coupled to RF generator 82 and impedance match network 84 in order to control the application of power to inductive coil 80. In an alternate embodiment, inductive coil 80 can be a “spiral” coil or “pancake” coil in communication with the plasma processing region 15 from above as in a transformer coupled plasma (TCP) reactor. The design and implementation of an inductively coupled plasma (ICP) source, or transformer coupled plasma (TCP) source, is well known to those skilled in the art.

Alternately, the plasma can be formed using electron cyclotron resonance (ECR). In yet another embodiment, the plasma is formed from the launching of a Helicon wave. In yet another embodiment, the plasma is formed from a propagating surface wave. Each plasma source described above is well known to those skilled in the art.

In the following discussion, a method of etching a substrate utilizing a plasma processing device is presented. For example, the plasma processing device can comprise various elements, such as described in FIGS. 2 through 6, or combinations thereof.

In one embodiment, the method of selectively etching silicon oxide or silicon nitride or both relative to silicon comprises a process chemistry having trifluoromethane (CHF₃), difluoromethane (CH₂F₂), oxygen (O₂), and argon (Ar). For example, a process parameter space can comprise a chamber pressure of about 5 to about 1000 mTorr (or from about 30 mTorr to about 50 mTorr), a CHF₃ process gas flow rate ranging from about 1 to about 1000 sccm, a CH₂F₂ process gas flow rate ranging from about 1 to about 1000 sccm, an O₂ process gas flow rate ranging from about 1 to about 1000 sccm, an Ar process gas flow rate ranging from about 1 sccm to about 2000 sccm, an upper electrode (e.g., element 70 in FIG. 5) RF power ranging from about 0 to about 2000 W, and a lower electrode (e.g., element 20 in FIG. 5) RF power ranging from about 10 to about 1000 W. Also, the upper electrode bias frequency can range from about 0.1 MHz to about 200 MHz, e.g., about 60 MHz. In addition, the lower electrode bias frequency can range from about 0.1 MHz to about 100 MHz, e.g., about 2 MHz.

In one example, a method of selectively etching silicon oxide or silicon nitride or both relative to silicon utilizing a plasma processing device such as the one described in FIG. 5 is presented. However, the methods discussed are not to be limited in scope by this exemplary presentation. Table I presents two process recipes including a first process recipe utilizing CHF₃ and Ar, and a second process recipe utilizing CHF₃, CH₂F₂, O₂, and Ar:

TABLE 1

| PROCESS | p (mtorr) | Gap (mm) | UEL P (W) | LEL P (W) | CHF3 (sccm) | Ar (sccm) | CH2F2 (sccm) | O2 (sccm) |
|---|---|---|---|---|---|---|---|---|
| 1 | 40 | 170 | 250 | 200 | 25 | 475 | 0 | 0 |
| 2 | 40 | 170 | 250 | 200 | 20 | 475 | 5 | 2 |

wherein p represents the gas pressure in the process chamber (millitorr, mtorr), gap represents the spacing between an upper electrode (e.g., element 70 in FIG. 5) and a lower electrode (e.g., element 20 in FIG. 5) (millimeters, mm), UEL P represents the RF power coupled to the upper electrode (e.g., element 70 in FIG. 5) (W, watts), LEL P represents the RF power coupled to the lower electrode (e.g., element 20 in FIG. 5) (W, watts), CHF3 represents the gas flow rate of CHF₃ (standard cubic centimeters per minute, sccm), Ar represents the gas flow rate of Ar (sccm), CH2F2 represents the gas flow rate of CH₂F₂ (sccm), and O₂ represents the gas flow rate of O₂ (sccm).

TABLE 2

| | | | | | Nitride |
|---|---|---|---|---|---|
| | oxide/ | nitride/ | Polysilicon | Oxide E/R | E/R |
| PROCESS | polysilicon | polysilicon | E/R (A/min) | (A/min) | (A/min) |
| 1 | 6.4 | 11.6 | 48.5 +/− 36.5% | 312.2 +/− 2.4% | 564.7 +/− 2.4% |
| 2 | 18.1 | 35.8 | 16.4 +/− 44.2% | 296.7 +/− 1.3% | 587.4 +/− 2.2% |

Table 2 presents the etch selectivity of silicon oxide relative to polysilicon (oxide/polysilicon, ratio of silicon oxide etch rate (E/R) to polysilicon etch rate), the etch selectivity of silicon nitride relative to polysilicon (nitride/polysilicon, ratio of silicon nitride etch rate to polysilicon etch rate), the polysilicon etch rate (Angstroms per minute, A/min), the silicon oxide etch rate (A/min), and the silicon nitride etch rate (A/min). Inspection of Table 2 indicates a large increase in etch selectivity when utilizing the second process recipe.

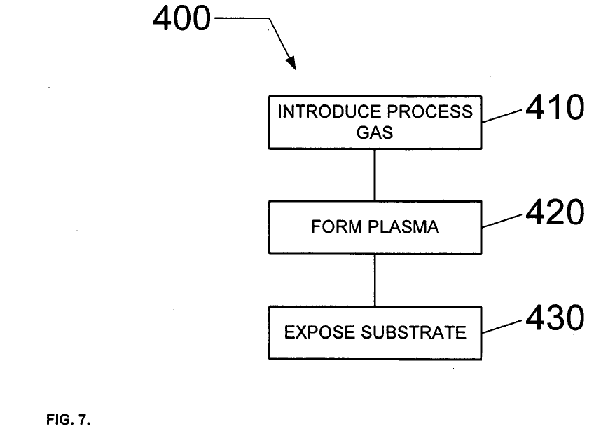

FIG. 7 presents a flow chart of a method for selectively etching silicon oxide or silicon nitride or both relative to silicon on a substrate in a plasma processing system according to an embodiment of the present invention. Procedure 400 begins in 410 in which a process gas is introduced to the plasma processing system, wherein the process gas comprises trifluoromethane (CHF₃), difluromethane (CH₂F₂), and an oxygen containing gas. Alternately, the process gas can further comprise an inert gas, such as a noble gas (e.g., argon).

In 420, a plasma is formed in the plasma processing system from the process gas using, for example, any one of the systems described in FIGS. 2 through 6, or combinations thereof.

In 430, the substrate is exposed to the plasma formed in 420 in order to etch silicon oxide or silicon nitride or both with high etch selectivity to silicon.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

What is claimed is:

1. A method of etching a substrate, comprising:
disposing said substrate in a plasma processing system, wherein said substrate comprises at least one silicon feature, and either a silicon oxide layer or a silicon nitride layer coupled to said silicon feature;
introducing a process gas comprising trifluoromethane (CHF₃), difluoromethane (CH₂F₂), an oxygen containing gas, and an optional inert gas;
forming a plasma from said process gas in said plasma processing system; and
exposing said substrate to said plasma in order to selectively etch said silicon oxide layer or said silicon nitride layer relative to said silicon feature.

2. The method of claim 1, wherein said introducing of said oxygen containing gas comprises introducing oxygen (O₂), NO, CO, NO₂, N₂O, or CO₂, or any combination of two or more gases thereof.

3. The method of claim 1, wherein said introducing of said optional inert gas comprises introducing a noble gas.

4. The method of claim 1, wherein said introducing of said process gas consists of introducing trifluoromethane (CHF₃), difluoromethane (CH₂F₂), oxygen (O₂), and argon (Ar).

5. The method of claim 1, wherein said silicon feature comprises a polysilicon feature.

6. The method of claim 5, wherein said polysilicon feature comprises a polysilicon gate for a transistor.

7. The method of claim 6, wherein said silicon oxide layer or said silicon nitride layer comprises an insulation spacer for said polysilicon gate.

8. The method of claim 1, wherein said forming of said plasma comprises coupling radio frequency (RF) power to a substrate holder upon which said substrate rests.

9. The method of claim 1, wherein of said forming said plasma comprises coupling radio frequency (RF) power to an upper electrode within said plasma processing system, wherein said upper electrode opposes a substrate holder upon which said substrate rests.

10. The method of claim 9, wherein said forming of said plasma further comprises coupling radio frequency (RF) power to said substrate holder.

11. The method of claim 1, further comprising:
setting a pressure in said plasma processing system for etching said substrate.

12. The method of claim 11, wherein said pressure ranges from approximately 5 millitorr to approximately 1000 millitorr.

13. The method of claim 11, wherein said pressure ranges from approximately 30 millitorr to approximately 50 millitorr.

14. A plasma processing system for etching a substrate, comprising:
a plasma processing chamber for facilitating the formation of a plasma from a process gas in order to etch a silicon oxide layer or a silicon nitride layer with high selectivity relative to a silicon feature; and
a controller coupled to said plasma processing chamber and configured to execute a process recipe utilizing said process gas, said process gas comprises trifluoromethane (CHF₃), difluoromethane (CH₂F₂), an oxygen containing gas, and an optional inert gas.

15. The plasma processing system of claim 14, wherein said oxygen containing gas comprises oxygen (O₂), NO, CO, NO₂, N₂O, or CO₂, or any combination of two or more gases thereof.

16. The plasma processing system of claim 14, wherein said optional inert gas comprises a noble gas.

17. The plasma processing system of claim 15, wherein said process gas consists of trifluoromethane (CHF₃), difluoromethane (CH₂F₂), oxygen (O₂), and argon (Ar).

18. The plasma processing system of claim 14, wherein said controller is further configured to set a pressure in said plasma processing chamber.

19. The plasma processing system of claim 18, wherein said pressure ranges from approximately 30 millitorr to approximately 50 millitorr.

20. A computer readable medium containing program instructions for execution on a computer system, which when executed by the computer system, cause the computer system to perform the steps of:
introducing a process gas in a plasma processing system comprising trifluoromethane (CHF₃), difluoromethane (CH₂F₂), an oxygen containing gas, and an optional inert gas;
forming a plasma from said process gas in said plasma processing system; and
exposing a substrate to said plasma, wherein said substrate comprises at least one silicon feature, and either a silicon oxide layer or a silicon nitride layer coupled to said silicon feature, in order to selectively etch said silicon oxide layer or said silicon nitride layer relative to said silicon feature.
